(19) United States
(12) Patent Application Publication
(10) Pub. No.: US 2018/0268087 A1
(43) Pub. Date: Sep. 20, 2018

(54) SYSTEM AND METHOD FOR EVALUATING A BUILDING PROJECT DESIGN

(71) Applicants: Patrick Tierney, San Francisco, CA (US); Abhijit Oak, Orinda, CA (US); Peter Wolff, Seattle, WA (US); Mark Thomas, Cupertino, CA (US)

(72) Inventors: Patrick Tierney, San Francisco, CA (US); Abhijit Oak, Orinda, CA (US); Peter Wolff, Seattle, WA (US); Mark Thomas, Cupertino, CA (US)

(21) Appl. No.: 15/803,592

(22) Filed: Nov. 3, 2017

Related U.S. Application Data
(60) Provisional application No. 62/471,288, filed on Mar. 14, 2017.

(51) Int. Cl. G06F 17/50; G06Q 10/06; G06Q 50/08; G06Q 50/16

(52) U.S. Cl. CPC G06F 17/5004; G06Q 50/165; G06Q 50/08; G06Q 10/06313

(57) ABSTRACT

A system for evaluating a building project design includes a database to store information regarding a plurality of building sites, and a plurality of building interior unit designs. A user interface (UI) receives input from which to select at least one of the plurality of building sites in the database on which to position the building project design, generate a proforma based on the selected building site(s), select one or more building interior unit designs based on the proforma, generate a building project design based on the proforma, and the selected building interior unit designs, evaluate the generated building project design according to one or more selected metrics, and generate a score based on the evaluation.

### RELATED APPLICATIONS

This application claims the benefit of the filing date of U.S. provisional patent application No. 62/471,288, filed Mar. 14, 2017, entitled “Vertically Integrated Multi-Domain Optimization of Buildings”, the entire contents of which are incorporated by reference under 37 C.F.R. § 1.57.

### TECHNICAL FIELD

Embodiments of the present invention relate to the field of building construction, and in particular to a process for designing a building in a more accurate, time-efficient manner.

### BACKGROUND

The current process for a building developer to build out a site and get it commissioned for occupancy may take 2 to 3 years, depending on the particular site and building type. This is not surprising if one considers the various phases in the current process. The first step is to contract the writing of a “Development Deal Brief” through an external contractor with a Preliminary Servicing Advice (providing water supply, sewer information, etc.) with the land owner. These documents are generated typically by an outside consultant at a relatively high cost, and over several months. The document would suggest target markets, target proforma numbers (i.e., financial outlay/outlook, also often referred to as a Unit Matrix), a development schedule, limitations of the site due to, for example, natural or legislative limitations. Because of the time to develop this document, an agreement typically is made with the land owner that the developer has the right to buy the land.

The next step is for an architect or designer to interpret the proforma numbers and design a site layout and building selection which meets the proforma requirements. This is either done manually, or assisted with a spreadsheet tool such as Excel. After determining the number of buildings and their placement on the site, the architect or designer will add detail to these “massing models”, selecting the specific units to be configured inside of the buildings, along with their layouts, materials, finishes, and/or fixtures. The model is then given to an internal or external engineer to “route” the various heating, ventilation, air-conditioning, plumbing, electrical, and/or data services through the building. This model would then be given to an internal construction engineer to select the specific off-site manufactured building components. The project may be evaluated at any point in the process for “target value control” which would evaluate if any of the metrics (e.g. cost, time to construction, energy use (sustainability), are on, below, or above target. Once “Construction Documents” are finalized, then the bidding process for construction services is initiated in parallel with request for building permit. Finally the construction process is initiated starting with the procurement of the necessary materials.

The above description is intentionally brief and, as such, not complete, however it does illustrate the complexities of this process. To further complicate things the process is rarely linear in that the results of one step of the process may cause one to revisit an earlier step. The current process has the following deficiencies: 1) the soft costs are too high; 2) the time required to complete these “soft cost” items is too long; 3) the process is not an optimized solution against a list of performance indices; 4) the uncertainty in development time and cost is too large; and 5) the uncertainty of the business case is too large. This is due in part to the uncertainty in the development time and cost but is also caused by the length of time from the start of the process to the commissioning for occupancy. The larger this time is, the larger the probability is for un-forecasted events that may alter the value in the market.

### BRIEF DESCRIPTION OF THE DRAWINGS

Embodiments are illustrated by way of example, and not by way of limitation, and can be more fully understood with reference to the following detailed description when considered in connection with the figures in which:

FIG. 1 illustrates an embodiment of the invention.

FIG. 2 illustrates an embodiment of the invention.

FIG. 3 illustrates a diagrammatic representation of a machine in the exemplary form of a computer system, in accordance with one embodiment of the invention.

### DETAILED DESCRIPTION

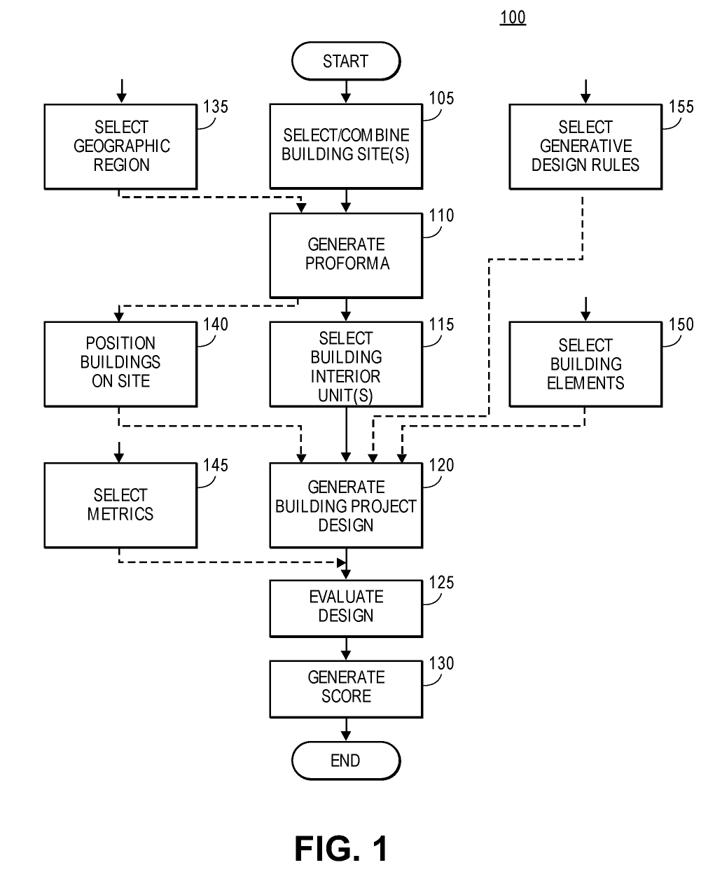

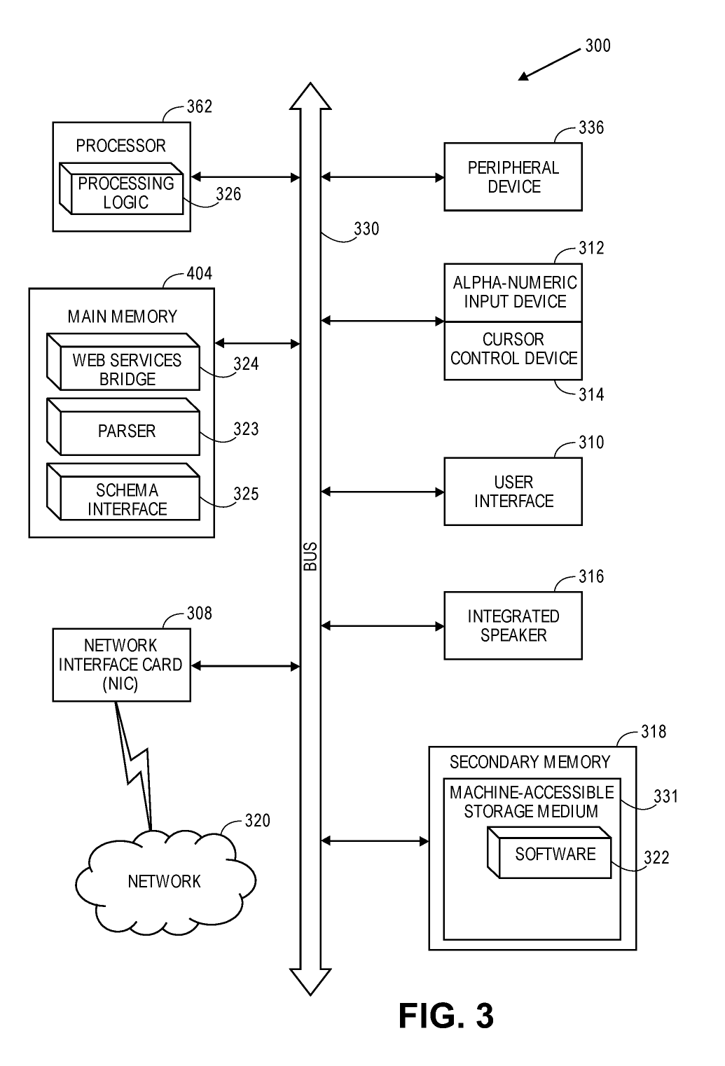

With reference to FIGS. 1 and 3 an embodiment of the invention includes a method 100 executed by a computer system to evaluate a building project design. A processor 362 executes software instructions 322 to perform the method. A storage device 331 accessible by the processor stores a database, and the database, in one embodiment, stores therein information regarding a number of building sites, and a plurality of building interior unit designs.

In one embodiment, a user interface (UI) 310 receives input and transmits output according to the software instructions 322 executed by the processor 362. In particular, the software instructions, when executed by the processor, cause the computer system to receive user input at 105 via the UI from which to select at least one of the building sites in the database on which to position the building project design. Site selection may be based on many factors such as those that determine the cost and time required to prepare a site for building, including, but not limited to: condition of the site, e.g., contamination present or not; requirements for preparation of site for building foundation, e.g., based on the soil conditions; road access; common area preparation; parking space preparation; landscaping needed to achieve the desired aesthetics, etc.

The software instructions then cause the system to generate a proforma, or unit matrix, at 110 based on the selected building site(s). The system executes software instructions that then select one or more building interior unit designs at 115 based on the proforma. A building project design based on the proforma, and the selected building interior unit designs, is then generated at 120. According to an embodiment, the building project design is evaluated at 125 according to one or more selected metrics. In one embodiment, the method generates a score at 130 based on the evaluation. In one embodiment, the metrics include, but are not limited to, one or more of: building installation costs, internal rate of returns (IRR), return on investment (ROI), building installation time, time to dry-in, time from slab on grade to occupancy, sustainability (e.g., Leadership in Energy and Environmental Design (LEED) building certification requirements), structural requirements, constructability, operating expenses, energy usage, maintenance costs, and combinations thereof.

In one embodiment, when the score generated at 130 fails to meet or exceed a threshold, the software instructions that when executed by the processor further cause the system to receive user input via the UI to select at 105 at least a new one of the building sites in which to reposition the building project design, generate a new proforma at 110 based on the newly selected building sites, and select one or more new building interior unit designs at 115 based on the new proforma. In such an embodiment, the system's software instructions then cause the system to generate a new building project design at 120 based on the new proforma, and the newly selected building interior unit designs. In one embodiment, the newly generated building project design is re-evaluated at 125 according to the one or more selected metrics, and a revised score is generated at 130 based on the re-evaluation.

In another embodiment, the database further stores therein information regarding a number of geographical regions. In such an embodiment, the software instructions that when executed by the processor, further cause the system to receive user input via the UI to select at 135 one of the geographical regions in the database in which to locate the building project design. In this embodiment, the proforma generated at 110 is further based on the selected one of the geographical regions. One embodiment of the invention makes use of a Geographic Information System (GIS) that describes geographic specific information about a building or building site. GIS data includes, but is not limited to: parcel outlines, parcel prices, parcel availability, population demographics (race, ethnicity), population ages, population incomes, economic indicators, land topography, historical temperature averages, historical precipitation averages, and building codes.

In one embodiment, the database further stores therein information regarding a number of the metrics. In such an embodiment, the software instructions that when executed by the processor, further cause the system to receive user input via the UI to select at 145 the one or more selected metrics.

In another embodiment, the software instructions that when executed by the processor cause the system to receive user input via the UI to combine the selected building sites for the building project design. The software instructions then combine at 105 the building sites for the building project in response to the user input to combine the selected building sites. In this embodiment, the proforma generated at 110 is further based on the combined building sites.

In one embodiment, the system's software instructions that when executed by the processor cause the system to generate a proforma at 110 further based on one or more criteria including but not limited to a number of buildings, a type for each of the buildings, a number of interior units per building, an interior unit mix per building, a building layout, and a building exterior envelope.

In another embodiment, the software instructions that when executed by the processor further cause the system to position buildings on the building site at 140. In such an embodiment, the software instructions that when executed by the processor cause the system to generate the building project design at 120 further based on the position of buildings on the building site. Just as building may be synthesized by combining (or configuring) a set of building elements, as described below, a building site may be synthesized by combining a set of site elements. Analogously, embodiments of the invention also may utilize building site element interfaces and building site design rules.

In one embodiment, the building site design rules (or design patterns) may be sourced by municipal building codes or they may be rules that may enhance the appearance of a building and/or land development (e.g. the amount of trees on a site, placement of tress on the site, the layout of roads, the proximity and density of buildings on a site, the location of pools, community rooms, and other amenities).

In one embodiment, the database further stores therein information regarding a number of building elements. In such an embodiment, the software instructions that when executed by the processor further cause the system to select a subset of the building elements at 150. The software instructions that when executed by the processor cause the system to generate the building project design at 120 do so further based on the selected subset of building elements. In one embodiment of the invention, because building installation cost, building installation time, and building energy use are important parameters in the design of a building it is important to have an accurate way of predicting these parameters. To that end, one or more of the following information or attributes may be stored in the database: a bill of material for each building element; a transformation cost in manufacturing for converting a bill of material to a corresponding building element; transportation costs of moving a building element from a factory to a construction site; additional materials needed on a building site to complete an installation of a building element; construction site labor and associated costs to install and complete a building element. It is further appreciated that each building element has attributes that influence the above calculation. These attributes may be specified by a developer, e.g., finishes (good, better, best) and features (smart home features, alternate energy source features), determined by geographical location, or a function of the parametric variability.

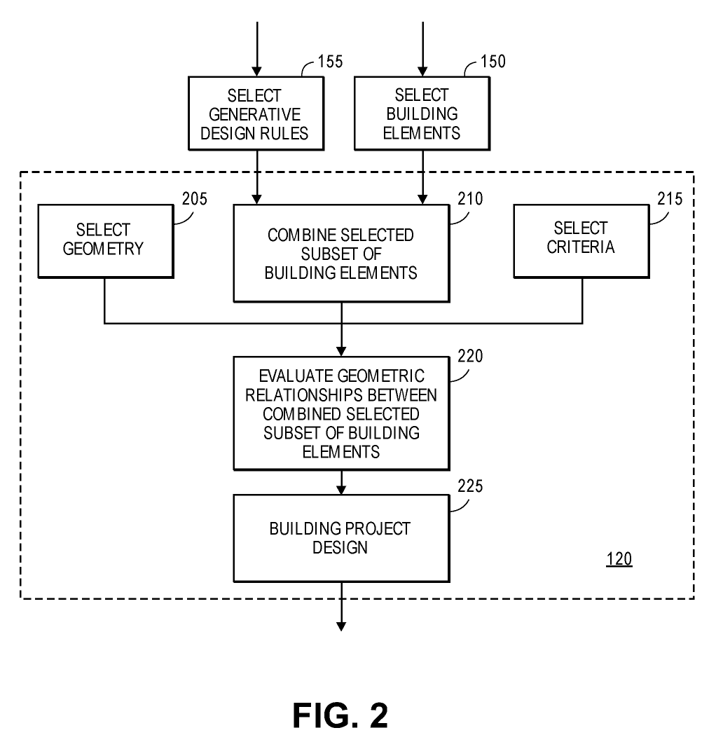

In one embodiment, the system's database further stores therein a number of generative design rules. In this embodiment, the software instructions that when executed by the processor further cause the system to generate the building project design do so further based on the generative design rules. In one embodiment, the generative design rules limit the building project design to a subset of possible permutations. In one embodiment, and with reference to FIGS. 1 and 2, the generative design rules are selected at 155 from a number of generative design rules including but not limited to building design rules, site design rules, functionality rules, appearance or aesthetic rules, and circulation rules. In one embodiment, the generative design rules substantially adhere to various codes and/or guidelines, including but not limited to municipal building codes, state building codes, federal building codes, international building codes, building design codes, aesthetic guidelines, and design rules relating to a building site, a building on the building site, and a location of a building on the building site.

In one embodiment, the software instructions that when executed by the processor cause the system to generate at 120 the building project design based on the generative design rules, cause the system to select a subset of the building elements at 150, and combine the selected subset of building elements according to the generative design rules into the building project design at 210. In one embodiment, the software instructions that when executed by the processor cause the system to select a subset of the building elements further cause the system to receive user input via the UI to select the subset of building elements at 150.

The described embodiments of the invention may make use of building elements and building element interfaces. Embodiments of the invention synthesize a building, in part or in whole, by combining (or configuring) a set of pre-fabricated building elements with specified building element interfaces using building design rules. The building elements can be configured in different combinations to create a large number of possible building permutations. These various permutations create buildings with a wide range of appearance and functionality, giving the occupant the experience of a custom design based on a standard set of building elements. The specific building design rules limit the possible ways building elements may be combined. For example, the building design rules may anticipate a series of potential options that tree and branch from the circulation of the building. Circulation, in the field of architecture, refers to the way people move through and interact with a building. For example, the circulation of a garden style apartment could be interpreted as climbing stairs to a landing, entering the apartment unit through an entry door into the apartment entry way.

One embodiment of the invention contemplates building elements of fixed dimensions which limit the possible synthesizable building solution space. Defining the building elements as parametric expands the solution space. One embodiment is simplified if the dependencies of a bill of materials (BOM) of a parametric building element automatically adjusts to the changes in parameters, e.g., if the dimensions of a kitchen expand then the placement of the fixtures in that kitchen automatically adjust to the expanded dimension.

In one embodiment, the software instructions that when executed by the processor further cause the system to combine at 210 the selected subset of building elements according to the generative design rules into the building project design cause the system to combine the selected subset of building elements according to the generative design rules into a proposed building project design at 210. The embodiment then evaluates at 220 a number of geometric relationships between the combined selected subset of building elements in the proposed building project design as acceptable according to a set of criteria selected at 215, and identify the proposed building project design as the final building project design at 225 based on the evaluation of the geometric relationships between the combined selected subset of building elements in the proposed building project design as acceptable according to the set of criteria. In such an embodiment, the system may receive user input via the UI to select the geometries of building elements and geometric relationships between or among building elements at 205.

Thus, as described above, embodiments of the invention gather and store information about the particulars of building construction in a database, then use that information with a set of algorithms to generate designs, details, and/or specifications for each part of the building construction supply chain. Embodiments of the invention then evaluate the generated design, for example, against a fitness function, wherein the fitness function is a mathematical function of the various metrics discussed earlier (install cost, install time, constructability, energy usage/sustainability, structural/loading analysis, return on investment). Through the use of an optimization algorithm, the design, detailing, and specification parameters converge to an optimum set of parameters for a building location, time, budget, energy use, and/or other constraints.

Embodiments of the invention first solve the problem of finding the optimum site to develop a building project, based on multiple internal and external sources of data related to building development. Second, the embodiments solve the problem of determining the optimum proforma of a site—the specific mix of unit sizes and types for a building development (e.g. develop 50 mid-size high end studio apartments, 40 small-sized low end studio apartments, 100 mid-sized mid end 1 bedroom apartments, etc.). Third, the embodiments solve the problem of determining the optimum layout of buildings on a site. A building development may take into account, for example, multiple overlapping city, county, state, and federal building codes, which place requirements on the location of buildings, setbacks from site perimeters, amount of parking, percentage of planted land, etc. Fourth, embodiments of the invention solve the problem of determining the optimum off-site manufacturing processes for a building. A pre-fabricated, or off-site-fabricated building can be constructed out of many number of possible components (e.g., a floor slab can be manufactured out of an open-web truss, or a cross laminated timber (CLT) slab), each with various price, time, energy usage, and qualitative tradeoffs. Embodiments of the invention select the optimum off-site-fabricated building components to match the constraints of building selection. Fifth, and finally, embodiments perform system routing through the building, determining the optimum position of building systems, including but not limited to electrical wiring, data wiring, plumbing, air conditioning, and heating.

As discussed above, embodiments of the invention may generate a proforma, building layout, building exterior envelope, and building interior unit selection based on the above described stored information and design patterns. One example procedure follows, though there are other procedures which can generate a detailed building. The example process starts with a parcel of land. The process may evaluate nearby parcels of land to determine if the parcels should be merged into a single larger parcel. One embodiment may then generate the buildable area: the total parcel areas where a building can be placed. Using information from at least the municipal, state, and federal code requirements, the embodiment calculates the total number of units and total building envelope. These total numbers are then potentially reduced by evaluating regional data, such as economic indicators, demographic data, and population growth projections. In one embodiment may adjust the total numbers based on market data, including intangible aspects of the region that match a particular type of buyer or renter. This same regional data is then used to calculate target sale and rental prices for the generated units. After determining the total potential buildable area, target unit counts, and target price points, the embodiment selects from a set of off-site fabricated building components to create a set of buildings which meet the target constraints. This involves selecting elements across various scales of the building process: the system may select pre-configured buildings, pre-configured sets of building units, the units themselves, the building components and their arrangements, such as walls, windows, or floor systems; and may involve selecting specific fixtures, such as high-end gold faucets or low-end steel faucets.

An embodiment of the invention may route building systems through the generated buildings. These systems are constrained to the street utility entry points, building site locations, foundations, floors, roofs, walls, doors and windows generated in the prior step. Each system typically links together a source (such as electric meter or junction box) to a sink (an outlet). This process passes through the generated building geometry, respecting obstacles such as doors, windows, or solid CLT flooring. Note that advancements with electrical and data technology, such as wireless light switches and wireless internet (WiFi), means that the system sources and sinks may not have to be physically connected, and are constrained by other parameters such as the ability for radio wave range, and radio wave ability to penetrate walls.

One embodiment of the invention generates a report on the generated design, and evaluates it with a fitness function. There may be one of several performance reports generated, each with an equivalent fitness function. For instance, the system can generate a cost report, summarizing the cost of each off-site fabricated building component, each building fixture, systems cost, as well as labor and transportation cost. The cost report is evaluated against a fitness function that attempts to minimize the total cost of the development. Another system can generate a time report, summarizing the time to procure, manufacture, transport, and install all of the elements of a development. The time report is evaluated against a fitness function that attempts to minimize the total time of development. Other systems may likewise generate reports on energy use or construction risk. Another embodiment can generate an energy usage report, summarizing the energy usage of the various building elements in the project. This energy usage report is evaluated against a fitness function that attempts to minimize the total energy usage of the development and/or the completed, fully-operational, building project.

One embodiment of the invention modifies previous design parameters to produce an alternate scheme, using an optimization function to move design parameters closer to the target fitness. This process may be repeated until it converges on a solution, or is stopped by the system, for example, based on user input. For instance, after generating a set of buildings, their off-site building components, fixtures, and systems, and having generated a cost report, if a cost report indicated costs were too high, the system may modify the original design parameters to produce a cheaper design, such as reducing the size of each apartment unit (reducing material), or reducing the choice of fixture to a cheaper option (low-end steel faucets instead of high-end gold faucets). This embodiment explores thousands if not millions of design options, and uses the reports from previously generated schemes to guide the selection of the next set of parameters, in a manner more efficient than a “brute force” exploration.

FIG. 3 illustrates a diagrammatic representation of a machine 300 in the exemplary form of a computer system, in accordance with one embodiment, within which a set of instructions, for causing the machine/computer system 300 to perform any one or more of the methodologies discussed herein, may be executed. In alternative embodiments, the machine may be connected (e.g., networked) to other machines in a Local Area Network (LAN), an intranet, an extranet, or the public Internet. The machine may operate in the capacity of a server or a client machine in a client-server network environment, as a peer machine in a peer-to-peer (or distributed) network environment, as a server or series of servers within an on-demand service environment. Certain embodiments of the machine may be in the form of a personal computer (PC), a tablet PC, a set-top box (STB), a Personal Digital Assistant (PDA), a cellular telephone, a web appliance, a server, a network router, switch or bridge, computing system, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 300 includes a processor 302, a main memory 304 (e.g., read-only memory (ROM), flash memory, dynamic random access memory (DRAM) such as synchronous DRAM (SDRAM) or Rambus DRAM (RDRAM), etc., static memory such as flash memory, static random access memory (SRAM), volatile but high-data rate RAM, etc.), and a secondary memory 318 (e.g., a persistent storage device including hard disk drives and a persistent database), which communicate with each other via a bus 330. Main memory 304 includes a web services bridge 324 and a schema interface 325 and a parser 323 by which to communicate with another web services environment, retrieve, and parse a schema to identify methods provided by the web service at the other web services environment in accordance with described embodiments. Main memory 304 and its sub-elements are operable in conjunction with processing logic 326 and processor 302 to perform the methodologies discussed herein.

Processor 302 represents one or more general-purpose processing devices such as a microprocessor, central processing unit, or the like. More particularly, the processor 302 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 302 may also be one or more special-purpose processing devices such as an application specific integrated circuit (ASIC), a field programmable gate array (FPGA), a digital signal processor (DSP), network processor, or the like. Processor 302 is configured to execute the processing logic 326 for performing the operations and functionality which is discussed herein.

The computer system 300 may further include a network interface card 308. The computer system 300 also may include a user interface 310 (such as a video display unit, a liquid crystal display, etc.), an alphanumeric input device 312 (e.g., a keyboard), a cursor control device 314 (e.g., a mouse), and a signal generation device 316 (e.g., an integrated speaker). The computer system 300 may further include peripheral device 336 (e.g., wireless or wired communication devices, memory devices, storage devices, audio processing devices, video processing devices, etc.).

The secondary memory 318 may include a non-transitory machine-readable storage medium or a non-transitory computer readable storage medium or a non-transitory machine-accessible storage medium 318 on which is stored one or more sets of instructions (e.g., software 822) embodying any one or more of the methodologies or functions described herein. The software 822 may also reside, completely or at least partially, within the main memory 304 and/or within the processor 302 during execution thereof by the computer system 300, the main memory 304 and the processor 302 also constituting machine-readable storage media. The software 322 may further be transmitted or received over a network 320 via the network interface card 308.

Although the invention has been described and illustrated in the foregoing illustrative embodiments, it is understood that the present disclosure has been made only by way of example, and that numerous changes in the details of implementation of the invention can be made without departing from the spirit and scope of the invention, which is only limited by the claims that follow. Features of the disclosed embodiments can be combined and rearranged in various ways.

What is claimed is:

1. A system for evaluating a building project design comprising:
a processor to execute software instructions;
a storage device accessible by the processor in which to store a database, the database to store therein information regarding a plurality of building sites, and a plurality of building interior unit designs;
a user interface (UI) via which to receive input and transmit output according to software instructions executed by the processor; and
software instructions that when executed by the processor cause the system to:
receive user input via the UI from which to select at least one of the plurality of building sites in the database on which to position the building project design;
generate a proforma based on the selected building site(s);
select one or more building interior unit designs based on the proforma;
generate a building project design based on the proforma, and the selected building interior unit designs;
evaluate the generated building project design according to one or more selected metrics; and
generate a score based on the evaluation.

2. The system of claim 1, wherein the database further to store therein information regarding a plurality of geographical regions, and wherein the software instructions that when executed by the processor further cause the system to:
receive user input via the UI to select one of the plurality of geographical regions in the database in which to locate the building project design; and
generate the proforma further based on the selected one of the plurality of geographical regions.

3. The system of claim 1, wherein the database further to store therein information regarding a plurality of metrics, and wherein the software instructions that when executed by the processor further cause the system to receive user input via the UI to select the one or more selected metrics.

4. The system of claim 1, further comprising software instructions that when executed by the processor cause the system to:
receive user input via the UI to combine the selected building sites for the building project design;
combine the building sites for the building project responsive to the user input to combine the selected building sites; and
wherein the software instructions that when executed by the processor cause the system to generate the proforma cause the system to generate the proforma further based on the combined building sites.

5. The system of claim 1, wherein the software instructions that when executed by the processor cause the system to generate a proforma based on the selected building sites cause the system to generate a proforma further based on one or more of a group consisting of: a number of buildings, a type for each of the buildings, a number of interior units per building, an interior unit mix per building, a building layout, and a building exterior envelope.

6. The system of claim 1, wherein the software instructions that when executed by the processor further cause the system to
position buildings on the building site; and
wherein the software instructions that when executed by the processor cause the system to generate the building project design cause the system to generate the building project design further based on the position of buildings on the building site.

7. The system of claim 1, wherein the database further to store therein information regarding a plurality of building elements, and wherein software instructions that when executed by the processor further cause the system to
select a subset of the plurality of building elements; and
wherein the software instructions that when executed by the processor cause the system to generate the building project design cause the system to generate the building project design further based on the selected subset of building elements.

8. The system of claim 1, wherein the metrics are selected from a group of metrics comprising one or more of: cost, internal rate of returns (IRR), return on investment (ROI), time to complete building project, time to dry-in, time from slab on grade to occupancy, sustainability, structural requirements, constructability, and combinations thereof.

9. The system of claim 1, wherein the software instructions that when executed by the processor further cause the system to:
when the score fails to meet or exceed a threshold:
receive user input via the UI to select at least a new one of the plurality of building sites in which to reposition the building project design;
generate a new proforma based on the newly selected building sites;
select one or more new building interior unit designs based on the new proforma; and
generate a new building project design based on the new proforma, and the newly selected building interior unit designs;
re-evaluate the new generated building project design according to the one or more selected metrics; and
generate a revised score based on the re-evaluation.

10. The system of claim 1, wherein the database further to store therein a plurality of generative design rules; and
wherein the software instructions that when executed by the processor further cause the system to generate the building project design further based on the generative design rules.

11. The system of claim 10, wherein the generative design rules limit the building project design to a subset of a plurality of permutations.

12. The system of claim 10, wherein the generative design rules are selected from a group of generative design rules consisting of: building design rules, site design rules, functionality rules, appearance or aesthetic rules, and circulation rules.

13. The system of claim 10 wherein the generative design rules substantially adhere to one or more of a group consisting of: municipal building codes, state building codes, federal building codes, international building codes, building design codes, aesthetic guidelines, and design rules relating to a building site, a building on the building site, and a location of a building on the building site.

14. The system of claim 10, wherein the database further to store therein information regarding a plurality of building elements, and wherein the software instructions that when executed by the processor further cause the system to generate the building project design further based on the generative design rules cause the system to:
select a subset of the plurality of building elements; and
combine the selected subset of building elements according to the generative design rules into the building project design.

15. The system of claim 14, wherein the software instructions that when executed by the processor further cause the system to select a subset of the plurality of building elements comprises software instructions that when executed by the processor further cause the system to receive users input via the UI to select the subset of the plurality of building elements.

16. The system of claim 14, wherein the software instructions that when executed by the processor further cause the system to combine the selected subset of building elements according to the generative design rules into the building project design cause the system to:
combine the selected subset of building elements according to the generative design rules into a proposed building project design;
evaluate a plurality of geometric relationships between the combined selected subset of building elements in the proposed building project design as acceptable according to a set of criteria; and
identify the proposed building project design as the building project design based on the evaluation of the geometric relationships between the combined selected subset of building elements in the proposed building project design as acceptable according to the set of criteria.
